(19) United States
(12) Patent Application Publication
(10) Pub. No.: US 2011/0110041 A1
(43) Pub. Date: May 12, 2011

(54) HEAT DISSPATION STRUCTURE OF ELECTRONIC APPARATUS

(76) Inventor: Shwin-Chung WONG, Hsinchu (TW)

(21) Appl. No.: 12/709,050

(22) Filed: Feb. 19, 2010

(30) Foreign Application Priority Data
Nov. 6, 2009 (TW) 098137752

(51) Int. Cl. H05K 7/20

(52) U.S. Cl. 361/697; 361/690

(57) ABSTRACT

A heat dissipation structure of an electronic apparatus includes a bendable vapor chamber with a large area. A small section of the vapor chamber is arranged to contact with the heat source of the electronic apparatus and a large remaining section of the vapor chamber contacts with an internal wall of the chassis of the electronic apparatus through appropriate bending. The working fluid in the vapor chamber absorbs the heat generated by the heat source and vaporizes. The heat-carrying vapor spreads within the vapor chamber to condense on a large condensation zone. The released heat is then dissipated to the atmosphere via the large area of the chassis and the heat dissipating fin structure thereon. Therefore, the heat dissipation structure provides efficient passive heat dissipation.

### BACKGROUND OF THE INVENTION

1. Field of the Invention

The present invention is related to a heat dissipation structure of an electronic apparatus, and more particularly to a heat dissipation structure that spreads heat evenly with a bendable vapor chamber of a large area.

2. Description of the Prior Art

Since the chips of a computer or a communication electronic apparatus generate a large amount of heat, an efficient heat dissipation mechanism is necessary to maintain high performance and a long life time. Typically, an active heat dissipation mechanism relying on dissipating heat with a fan is adopted. Although the fan enhances heat dissipation, the noise and the life time of the fan become an issue, particularly the burnout of the chips when the fan breaks down. Therefore, in certain applications, such as outdoor communication devices or industrial computers, a passive dissipation mechanism based on quiet and durable natural convection may be adopted.

In current passive heat dissipation mechanisms, thermally conductive aluminum chassis are commonly used. For further improvement, heat pipes may be employed. Usually, the original tubular heat pipes would be bent and flattened before being attached to or embedded into the internal wall of the chassis. However, since the width of the flattened heat pipe is limited, multiple heat pipes are required for heat distribution to a large area. Such configuration becomes increasingly complicated as the number of heat sources in the electronic apparatus increases.

When a large-area flat-plate heat pipe, commonly called vapor chamber, is adopted, not only multiple heat sources can be covered all at once, but also heat spreading can be more uniform. However, conventional vapor chambers are too thick to be bent easily; therefore, it is difficult for them to match with the space allocation of the electronic apparatus. Having developed a thin and bendable novel vapor chamber, the inventor herein applies it to the heat dissipation of an electronic apparatus.

### SUMMARY OF THE INVENTION

In order to solve the aforementioned problems, an aspect of the present invention is to provide a heat dissipation structure of an electronic apparatus with a large-area bendable vapor chamber such that a small portion of the bent vapor chamber is attached to the surface of a plurality of heat sources, and the remaining portion is attached to an internal wall of the chassis. The heat spread by the vapor chamber is effectively dissipated to the atmosphere through the large area of the chassis.

According to an embodiment of the present invention, a heat dissipation structure of an electronic apparatus includes a bendable vapor chamber disposed inside a chassis of the electronic apparatus. Also inside the chassis is a circuit board containing at least a heat source. The vapor chamber is bent into multiple sections, including at least a first flat section, a second flat section and a bent section between the first flat section and the second flat section. The area of the second flat section is larger than that of the first flat section, wherein the first flat section contacts with the heat source on the circuit board and the second flat section contacts with an internal wall of the chassis.

According to another embodiment of the present invention, the heat dissipation structure includes a first bendable vapor chamber disposed inside a chassis of the electronic apparatus. A circuit board containing at least a first heat source and at least a second heat source is also disposed inside the chassis. The chassis includes a first internal wall and a second internal wall facing against each other. At least one of the first vapor chamber and the second vapor chamber is bent into multiple sections including at least a first flat section, a second flat section and a bent section between the first flat section and the second flat section. The area of the second flat section is larger than that of the first flat section, wherein the first flat section of the first vapor chamber contacts with the first heat source, and the second flat section contacts with the first internal wall; the first flat section of the second vapor chamber contacts with the second heat source and the second flat section contacts with the second internal wall.

### BRIEF DESCRIPTION OF THE DRAWINGS

FIG. 1 is a cross-sectional diagram schematically illustrating the heat dissipation structure applied in the electronic apparatus according to one embodiment of the present invention;

FIG. 2 is a top-view diagram schematically illustrating a portion of FIG. 1;

FIG. 3 is a cross-sectional diagram schematically illustrating the heat dissipation structure applied in the electronic apparatus according to another embodiment of the present invention;

FIG. 4 is a cross-sectional diagram schematically illustrating the heat dissipation structure applied in the electronic apparatus according to another embodiment of the present invention; and

FIG. 5 is a cross-sectional diagram schematically illustrating the heat dissipation structure applied in the electronic apparatus according to another embodiment of the present invention.

### DESCRIPTION OF THE PREFERRED EMBODIMENT

The detailed explanation of the present invention is described in the following. The described preferred embodiments are presented for the purposes of illustrations and description, rather than to limit the scope of the present invention.

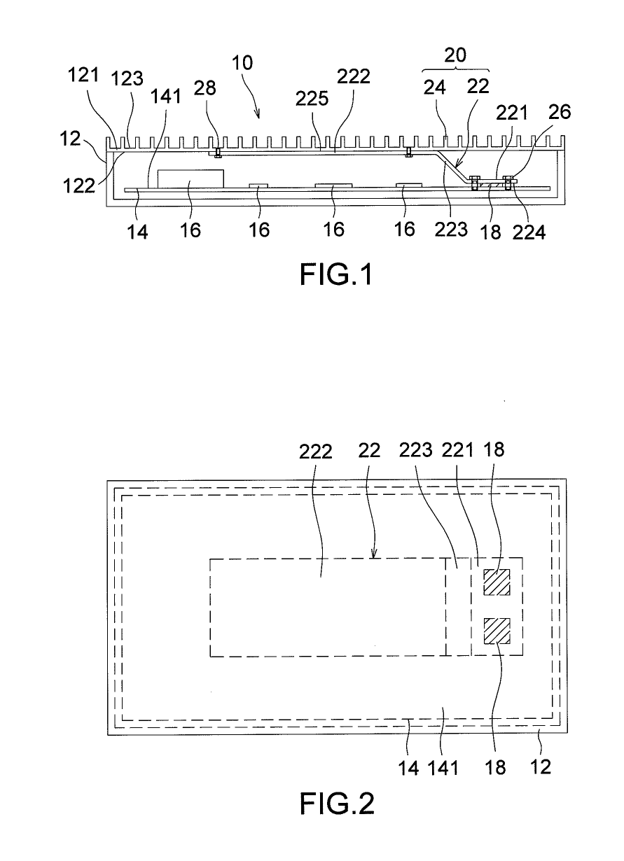

FIG. 1 is a cross-sectional diagram schematically illustrating the heat dissipation structure applied in an electronic apparatus according to an embodiment of the present invention. FIG. 2 is a top-view diagram schematically illustrating a portion of FIG. 1. As shown in FIG. 1, a general electronic apparatus 10 primarily includes a hollow chassis 12, and a circuit board 14 disposed inside the chassis 12. Configured on the circuit board 14 are various electronic components 16, including at least a heat source 18, such as the central processor unit (CPU) or another component to be cooled. As shown in FIG. 2, an example of two heat sources 18 located on the upper surface 141 of the circuit board 14 is used to illustrate the characteristics of the heat dissipation structure of the present invention.

A heat dissipation structure 20, in reference to FIG. 1, includes a bendable vapor chamber 22, whose thickness is between 0.8 mm and 1.5 mm. According to the present embodiment, the vapor chamber 22 is bent to match with the distribution of the heat sources 18. That is, the vapor chamber 22 is bent into a first flat section 221, a second flat section 222 and a bent section 223 between the first flat section 221 and the second flat section 222. The length of the bent section 223 allows the lower surface 224 of the first flat section 221 to contact with the heat sources 18, and the upper surface 225 of the second flat section 222 to contact with the internal wall 122 at the top 121 of the chassis 12.

As shown in FIG. 1, the heat dissipation structure 20 further comprises a heat dissipating fin structure 24 disposed on the external wall 123 at the top 121 of the chassis 12. The surface of the external wall 123 of the chassis 12 and the external surface of the heat dissipating fin structure 24 may be treated with, for example, anodization, painting or coating to increase the radiative emissivity of the surface, whereby heat dissipation efficiency is further enhanced. In addition, the heat dissipation structure 20 further includes a plurality of first fastening elements 26 for fastening the first flat section 221 onto the circuit board 14, allowing the lower surface 224 of the first flat section 221 to contact with the plurality of heat sources 18. A plurality of second fastening elements 28 fasten the second flat section 222 onto the chassis 12, allowing the upper surface 225 of the second flat section 222 to contact tightly with the internal wall 122 of the chassis 12. An interface material (not shown), such as thermal pad, thermal grease, thermal paste, or thermal tape, etc., can be used to reduce the thermal contact resistances between the first flat section 221 and the heat sources 18, and between the second flat section 222 and the internal wall 122.

Here, the vapor chamber 22 is a sealed chamber containing a small amount of working fluid (not shown), and at least a layer of wick structure (not shown) attached to the internal walls of the chamber. The small amount of working fluid charged in the vapor chamber vaporizes by absorbing the heat of the plurality of heat sources 18 in contact with the first flat section 221. The heat-carrying vapor spreads evenly within the chamber and condenses on a large area of the condensation zone (including the bent section 223 and the second flat section 222). The released heat dissipates to the external atmosphere through the large area of the chassis 12 and the heat dissipating fin structure 24.

It is noted that the number of the first flat section 221, the second flat section 222 or the bent section 223 can be but not limited to one. The vapor chamber 22 may be bent arbitrarily according to the spatial distribution of the plurality of heat sources 18. This is also an important feature of the present invention that provides the advantage of efficient heat dissipation.

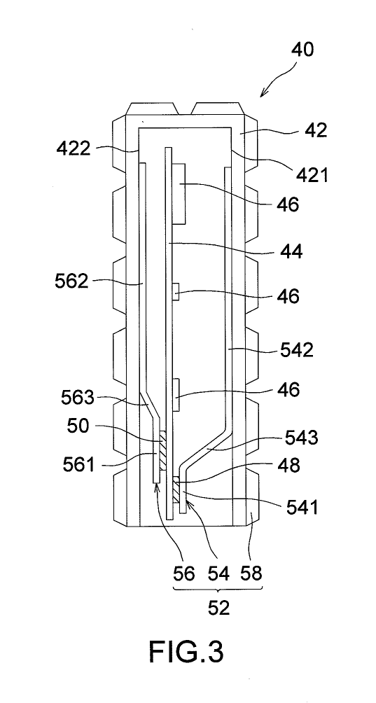

FIG. 3 is a cross-sectional diagram illustrating the heat dissipation structure applied in an electronic apparatus according to another embodiment of the present invention. The electronic apparatus 40 includes an upright chassis 42 containing a first internal wall 421 and a second internal wall 422 facing against each other; and a circuit board 44 disposed vertically in the upright chassis 42. Various electronic components 46 are configured on the circuit board 44. In an embodiment, a first heat source 48 and a second heat source 50 are located respectively on the two opposite faces of the lower portion of the circuit board 44.

The heat dissipation structure 52 of the present embodiment includes two bendable vapor chambers, respectively referred to as the first vapor chamber 54 and the second vapor chamber 56. At least one of the first vapor chamber 54 and the second vapor chamber 56 is bent into a first flat section 541 or 561, a second flat section 542 or 562, and a bent section 543 or 563, wherein the bent section 543 or 563 connects between the first flat section 541 or 561 and the second flat section 542 or 562, and the area of the second flat section 542 or 562 is larger than that of the first flat section 541 or 561. The first flat section 541 of the first vapor chamber 54 contacts with the first heat source 48, and the second flat section 542 contacts with the first internal wall 421 of the chassis 42. The first flat section 561 of the second vapor chamber 56 contacts with the second heat source 50 and the second flat section 562 contacts with the second internal wall 422 of the chassis. Again, an interface material (not shown), such as thermal pad, thermal grease, thermal paste, or thermal tape, etc., can be applied at the interfaces between the vapor chambers, the heat sources, and the internal walls. If the second heat source 50 is located near the second internal wall 422 of the chassis 42, the second vapor chamber 56 would not have to be bent for attachment with the second internal wall 422 of the chassis 42, but instead through a metal or nonmetal thermal pad that could bridge the gap therebetween.

The heat dissipation structure 52 further includes at least a heat dissipating fin structure 58 disposed on at least one of the two opposite external walls of the chassis 42. Preferably, as shown in FIG. 3, the heat dissipating fin structure 58 is arranged to cover the maximum possible region of the external walls of the chassis 42.

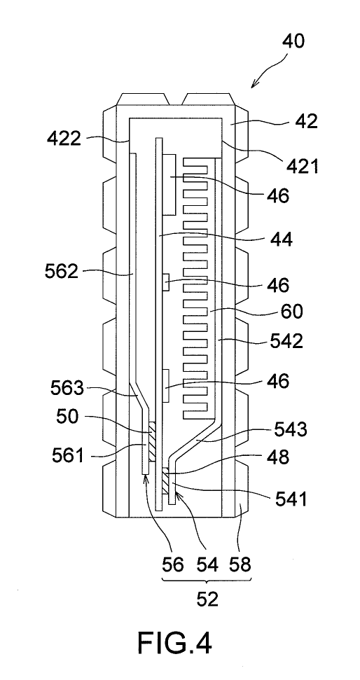

FIG. 4 is a cross-sectional diagram schematically illustrating the heat dissipation structure applied in the electronic apparatus according to another embodiment of the present invention. According to this embodiment, a heat sink 60 is disposed on a side wall of the second flat section 542 of the first vapor chamber 54, the side wall opposite to the side wall of the second flat section 542 which contacts with the first internal wall 421. According to an embodiment, the second flat section 542 of the first vapor chamber 54 has a larger distance from the circuit board 44 than that of the second vapor chamber 56. For further enhancing heat dissipation, according to an embodiment, a plurality of through holes (not shown) can be configured at appropriate locations on the chassis 42 to improve air circulation. Moreover, the additional features of this embodiment may also be applied to the embodiment illustrated in FIG. 1.

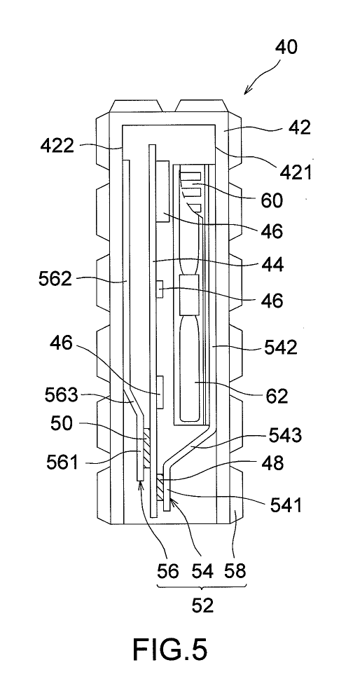

FIG. 5 is a cross-sectional diagram schematically illustrating the heat dissipation structure applied in the electronic apparatus according to another embodiment of the present invention. This embodiment is an extension of the embodiment presented in FIG. 4. According to the embodiment, in order to further enhance heat dissipation in the electronic apparatus, a fan 62 is disposed to collocate with the heat sink 60. While in FIG. 5 the fan 62 is located at the side of the heat sink 60, other locations for disposing the fan 62 are possible. For example, the fan 62 may also be located on top of the heat sink 60. Moreover, the additional features of this embodiment may also be applied to the embodiment illustrated in FIG. 1.

Additionally, an interface material (not shown), such as thermal pad, thermal grease, thermal paste, or thermal tape, etc., can be applied at the interface between the first vapor chamber 54 and the heat sink 60, and/or either between the heat sink 60 and the fan 62 or between the first vapor chamber 54 and the fan 62 to decrease the thermal resistances therebetween.

To summarize the foregoing descriptions, the present invention adopts a bendable vapor chamber with a large area, of which a small section contacts with the heat sources, and a large portion of the remaining section contacts with an internal wall of a chassis through proper bending. The working fluid of the vapor chamber absorbs the heat and become heat-carrying vapor that spreads within the chamber and condenses on the large condensation area. The released heat is then dissipated to the external atmosphere through the large area of the chassis and the heat dissipating fin structure thereon. Therefore, the present invention provides efficient passive heat dissipation for electronic apparatus.

While the invention can be subject to various modifications and alternative forms, specific examples thereof have been shown in the drawings and have been described in detail. It should be understood, however, that the invention is not to be limited to the particular forms disclosed, but to the contrary, the invention is to cover all modifications, equivalents, and alternatives falling within the spirit and scope of the appended claims.

What is claimed is:

1. A heat dissipation structure of an electronic apparatus, wherein said electronic apparatus comprises at least a chassis and a circuit board disposed inside said chassis, wherein said circuit board contains at least a heat source; and said heat dissipation structure comprises:
a bendable vapor chamber disposed inside said chassis and said vapor chamber is bent into multiple sections including at least a first flat section, a second flat section and a bent section between said first flat section and said second flat section, and the area of said second flat section is larger than that of said first flat section, wherein said first flat section contacts with said heat source on said circuit board, and said second flat section contacts with an internal wall of said chassis.

2. The heat dissipation structure of the electronic apparatus according to claim 1, further comprising a heat dissipating fin structure disposed on an external wall of said chassis.

3. The heat dissipation structure of the electronic apparatus according to claim 1, wherein the thickness of said vapor chamber is between 0.8 mm to 1.5 mm.

4. The heat dissipation structure of the electronic apparatus according to claim 1, wherein said circuit board contains a plurality of heat sources disposed on the same face of said circuit board such that said first flat section of said vapor chamber contacts with said plurality of heat sources at the same time.

5. The heat dissipation structure of the electronic apparatus according to claim 1, further comprising a plurality of first fastening elements for fastening said first flat section onto said circuit board so that said first flat section contacts with said heat source.

6. The heat dissipation structure of the electronic apparatus according to claim 1, further comprising a plurality of second fastening elements for fastening said second flat section onto said internal wall of the chassis.

7. The heat dissipation structure of the electronic apparatus according to claim 1, further comprising an interface material arranged between said heat source and said first flat section, and/or between said internal wall and said second flat section.

8. The heat dissipation structure of the electronic apparatus according to claim 7, wherein said interface material is selected from the group consisting of thermal pad, thermal grease, thermal paste, and thermal tape.

9. The heat dissipation structure of the electronic apparatus according to claim 1, wherein the surface of at least an external wall of said chassis is treated to increase the radiative emissivity thereof.

10. The heat dissipation structure of the electronic apparatus according to claim 2, wherein the external surface of said heat dissipating fin structure is treated to increase the radiative emissivity thereof.

11. The heat dissipation structure of the electronic apparatus according to claim 1, further comprising a heat sink disposed on a side wall of said second flat section of said vapor chamber, the side wall opposite to the side wall of said second flat section which contacts with said internal wall.

12. The heat dissipation structure of the electronic apparatus according to claim 11, further comprising a fan collocating with said heat sink.

13. A heat dissipation structure of an electronic apparatus, wherein said electronic apparatus comprises at least a chassis including a first internal wall and a second internal wall facing against each other, and a circuit board inside said chassis, wherein said circuit board contains at least a first heat source and at least a second heat source disposed on the opposite faces of said circuit board; and said heat dissipation structure comprises:
a first bendable vapor chamber and a second bendable vapor chamber disposed inside said chassis, and at least one of said first vapor chamber and said second vapor chamber is bent into multiple sections including at least a first flat section, a second flat section and a bent section between said first flat section and said second flat section, and the area of said second flat section is larger than that of said first flat section, wherein said first flat section of said first vapor chamber contacts with said first heat source, and said second flat section contacts with said first internal wall; said first flat section of said second vapor chamber contacts with said second heat source and said second flat section contacts with said second internal wall.

14. The heat dissipation structure of the electronic apparatus according to claim 13, further comprising at least a heat dissipating fin structure disposed on at least one of the two opposite external walls of said chassis.

15. The heat dissipation structure of the electronic apparatus according to claim 13, wherein said chassis is an upright chassis, and said circuit board is vertically disposed inside said chassis.

16. The heat dissipation structure of the electronic apparatus according to claim 15, wherein said first heat source and said second heat source are respectively located on the lower portion of the opposite two faces of said circuit board.

17. The heat dissipation structure of the electronic apparatus according to claim 13, wherein the thicknesses of said first vapor chamber and said second vapor chamber are between 0.8 mm to 1.5 mm.

18. The heat dissipation structure of the electronic apparatus according to claim 13, further comprising a plurality of first fastening elements for fastening said first flat section of said first vapor chamber and said second vapor chamber onto said circuit board so that said first flat section of said first vapor chamber and said second vapor chamber contact respectively with said first heat source and said second heat source.

19. The heat dissipation structure of the electronic apparatus according to claim 13, further comprising a plurality of second fastening elements for fastening said second flat section of said first vapor chamber and said second vapor chamber respectively onto said first internal wall and said second internal wall of said chassis.

20. The heat dissipation structure of the electronic apparatus according to claim 13, further comprising an interface material arranged between said first heat source and said first flat section of said first vapor chamber, said second heat source and said first flat section of said second vapor chamber, said first internal wall and said second flat section of said first vapor chamber, and/or said second internal wall and said second flat section of said second vapor chamber.

21. The heat dissipation structure of the electronic apparatus according to claim 20, wherein said interface material is selected from the group consisting of thermal pad, thermal grease, thermal paste, and thermal tape.

22. The heat dissipation structure of the electronic apparatus according to claim 13, wherein at least an external surface of said chassis is treated to increase the radiative emissivity thereof.

23. The heat dissipation structure of the electronic apparatus according to claim 14, wherein the external surface of said heat dissipating fin structure is treated to increase the radiative emissivity thereof.

24. The heat dissipation structure of the electronic apparatus according to claim 13, further comprising a heat sink disposed on a side wall of said second flat section, the side wall opposite to the side wall of said second flat section which contacts with said first internal wall or said second internal wall.

25. The heat dissipation structure of the electronic apparatus according to claim 24, further comprising a fan collocating with said heat sink.
